(19) United States
(12) Patent Application Publication
(10) Pub. No.: US 2004/0055534 A1
(43) Pub. Date: Mar. 25, 2004

(54) Fluid applicator for permeable substrates

(75) Inventors: Dieter Friedrich Zeiffer, Iron Station, NC (US); Hermann A. Neupert, Belmont, NC (US)

Correspondence Address: KENNEDY COVINGTON LOBDELL & HICKMAN, LLP, 214 N. TRYON STREET, HEARST TOWER, 47TH FLOOR, CHARLOTTE, NC, 28202, US

(73) Assignee: Gaston Systems, Inc., Stanley, NC

(21) Appl. No.: 10/246,915

(22) Filed: Sep. 19, 2002

(51) Int. Cl. C23C 14/00; B05C 5/00; B05B 15/12

(52) U.S. Cl. 118/326; 118/400; 118/423; 118/50

(57) ABSTRACT

An applicator apparatus for applying a preferably foamed treating fluid to a traveling permeable fabric, web or other substrate can include either or both of a low-pressure exhaust chamber on the opposite side of the substrate from the applicator nozzle and a flexible lip extending from either or both sides of the nozzle opening, between the nozzle and the substrate. The applicator apparatus is particularly adapted and well-suited for lightly coating or treating the surface of a fragile and fast moving substrate, without deformation or breakage of the substrate and without undesirable substrate penetration.

### BACKGROUND AND SUMMARY OF THE INVENTION

The present invention relates generally to applicator apparatuses for applying a flowable liquid treatment fluid across the width of a traveling substrate. More particularly, the invention relates to such applicator apparatuses that are especially well-suited for applying a foamed treatment fluid across the width of a relatively thin, porous, permeable or semi-permeable substrate, including non-woven fibrous textiles, such as tissues or tissue-like fabrics, for example, or even woven porous or permeable substrates. Other substrate examples include, but are not limited to, webs or sheets of textile or non-textile materials, woven or non-woven or multi-stranded materials, flexible or non-flexible sheets or sheet-like materials, knitted substrates, cross-linked cellulose, loose fiber or impregnated substrates, thin tissue substrates, carpets or other floor coverings, continuous filament substrates, nonwoven and unbound glass or other fibrous materials, and other substrates known to those skilled in the art that are at least partially permeable. Examples of fluid materials to be applied to such substrates include, but are not limited to, dyes, sizings, stains, scents, colorants or other treating fluids known to those skilled in the art.

The finishing of textile fabrics or other sheet-like substrates typically involves applying dyes, sizings, stains or other known “treating fluids” to the fabric or other substrate. Various methods and apparatuses have been used for this purpose, including passing the substrate through an immersion bath of the treating fluid, by which the fabric or other sheet takes on a significant amount of the treating fluid. In these instances, the excess fluid absorbed or adsorbed by the fabric or sheet has to be removed and properly disposed of, requiring costly, time-consuming or energy-wasting equipment and processes, such as drying or curing of the substrate, for example. In addition, in applications where it is not desirable for the substrate to completely absorb the treating fluid, it is difficult to adequately coat a surface of the substrate without the treating material penetrating too deeply.

Further, there is a continuing emphasis in textile and other manufacturing processes upon cost-effectiveness of equipment, speed of application, energy efficiency, and increased uniformity of distribution of the treating fluid. These and other problems have been significantly alleviated or minimized through the application of the treating dyes, sizings, stains, scents, colorants or other fluid treating materials in a foamed condition to significantly reduce the amount of wet pick-up by the fabric or other substrate being treated, resulting in a minimal amount of required substrate drying, if any, as well as reduced waste and disposal concerns.

Such light and relatively non-penetrating surface coatings are particularly difficult to obtain where the speed of the traveling substrate results in the creation of a thin boundary layer of air that acts as a barrier on the surface to be coated. In addition, because the substrates to be coated are frequently very thin and fragile, any substantial contact force by the applicator's nozzle must be eliminated. However, too much of a gap between the nozzle and the substrate can result in foam breakdown or separation in the case of foamed treating fluids, or hard-to-control or uneven applications in the case of non-foamed treating fluids. In addition, the ever-increasing demand for faster traveling substrate speeds further exacerbates these application problems. Difficulties still exist, however, when lightly coating thin and fragile substrates, especially at high speeds.

The present invention seeks to overcome these disadvantages and further improve on the above-described methods and apparatuses for applying a fluid, preferably a foamed fluid, across the lateral or transverse width of a longitudinally traveling substrate that is at least semi-permeable. In a preferred embodiment, the present invention includes a fluid applicator having a transversely elongated fluid dispensing nozzle spaced adjacent a first side of the traveling permeable substrate for depositing the fluid material thereon. Preferably the nozzle is disposed at an acute angle, or at least no more than approximately ninety degrees, relative to the substrate, with the nozzle's discharge opening typically oriented toward the substrate and generally longitudinally downstream.

A low-pressure chamber can be positioned adjacent a second, opposite side of the traveling permeable substrate, preferably at a longitudinal position generally opposite the nozzle. The pressure within the preferably laterally elongated low-pressure chamber is lower than the ambient pressure, thus causing boundary layer air or other air adjacent the first side of the traveling permeable substrate to flow through the substrate and into said low-pressure chamber. However, this chamber pressure should no lower than necessary to draw the air through the permeable substrate without deforming or breaking it.

An air conveying mechanism, with its inlet in fluid communication with the outlet of the low-pressure chamber, is provided for exhausting the air from the low-pressure chamber through the conveying mechanism's outlet. Such an air conveying mechanisms can include a fan, a blower, a vacuum pump, or any of a wide variety of air conveying mechanisms known to those skilled in the art.

Whether or not the applicator of the present invention is equipped with the above-described low-pressure chamber on the opposite side of the traveling permeable substrate, a transversely elongated flexible lip can be provided to extend between the nozzle and the traveling permeable substrate. Such flexible lip can extend from either a longitudinally upstream or downstream side or edge of the transversely elongated nozzle discharge opening. If upstream, the flexible lip serves to substantially block or displace the above-mentioned layer of air adjacent the first side of the substrate from interfering with the application of the treating fluid to the first side of the substrate. If downstream, such flexible lip exerts a relatively light force on the treating fluid as it is applied to the surface of the substrate, but is preferably held out of actual contact with the substrate by the presence of the treating fluid itself.

In order to obtain both of these benefits, an applicator according to the present invention can also optionally be equipped with a second of the flexible lips described above, with the first and second flexible lips being spaced apart on opposite sides or edges of the fluid material being deposited from the nozzle onto the first side of the traveling permeable substrate. In such an optional application, the upstream flexible lip contacts the substrate very lightly prior to the fluid material being deposited on its first side, and the downstream flexible lip is held out of actual contact with the traveling permeable substrate by the fluid material being deposited onto its first side, as described above. It should be noted that the transverse lateral dimensions of these flexible lips and the nozzle discharge opening, as well as that of the low-pressure chamber mentioned above, are preferably generally coextensive with the lateral width of the traveling substrate. As one skilled in the art will readily recognize from the following discussion, the need or desirability for any one of these flexible lip or low-pressure chamber components, or for various combinations of some or all of these components, depends upon factors such as the material, thickness, texture, fragility and/or speed of the traveling permeable substrate S in a given application.

The treating fluid material, which is preferably in a foamed state, can thus be deposited onto the surface of a substrate without penetration, without breaking a relatively thin and fragile substrate due to applicator nozzle contact, and without the preferred foamed treating fluid disintegrating or breaking down during application as a result of too large of a gap between the nozzle and the substrate.

Additional objects, advantages and features of the present invention will become apparent from the following description and the appended claims, taken in conjunction with the accompanying drawings.

### BRIEF DESCRIPTION OF THE DRAWINGS

FIG. 1 is a perspective view of a preferred embodiment of a fluid distribution apparatus for applying a treating fluid to a traveling permeable substrate, according to the present invention.

FIG. 2 is an upstream elevation view of the applicator portion of the apparatus of FIG. 1, with portions shown in cross-section.

FIG. 3 illustrates an exemplary applicator nozzle and opposite low-pressure chamber arrangement according to the present invention.

FIG. 4 illustrates another exemplary applicator nozzle and low-pressure chamber similar to that of FIG. 3, but with a flexible lip along the lower or upstream edge of the nozzle discharge opening.

FIG. 5 illustrates yet another exemplary applicator nozzle and low-pressure chamber similar to that of FIGS. 3 and 4, but with a flexible lip along the upper or downstream edge of the nozzle discharge opening.

FIG. 6 illustrates still another exemplary applicator nozzle and low-pressure chamber similar to that of FIGS. 3 through 5, but with a flexible lip along both the lower or upstream edge and the upper or downstream edge of the nozzle discharge opening.

FIG. 7 illustrates another exemplary applicator nozzle similar to that of FIG. 4, with a flexible lip along the upper or downstream edge of the nozzle discharge opening, but with no low-pressure chamber on the opposite side of the traveling permeable substrate.

### DESCRIPTION OF THE PREFERRED EMBODIMENTS

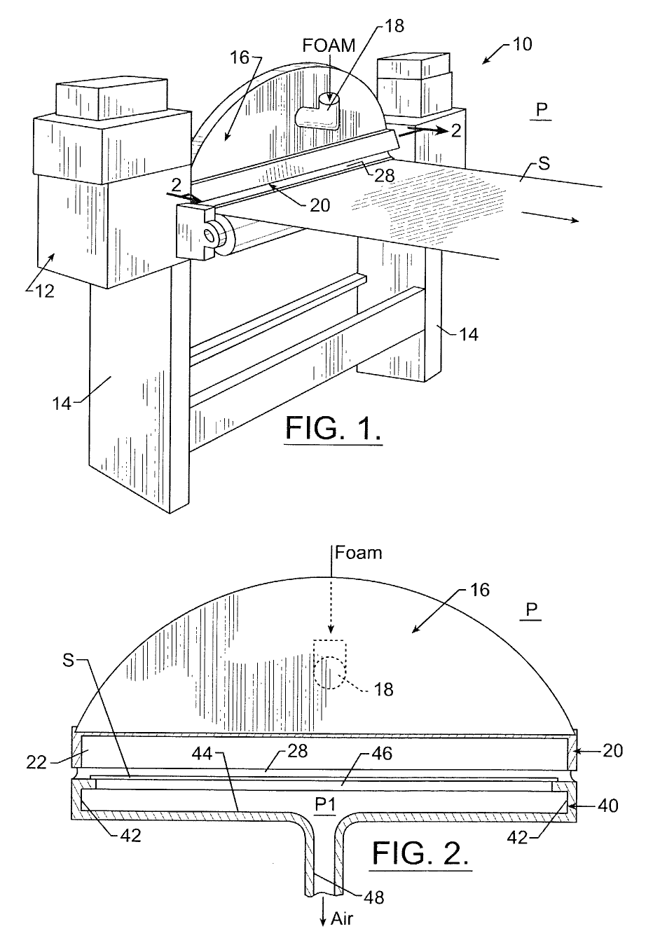

FIGS. 1 through 7 of the accompanying drawings depict merely exemplary embodiments of a fluid applicator assembly, according to the present invention, for treating a traveling fabric that is at least semi-permeable, with a preferably foamed treatment fluid. Such illustrations are shown for purposes of illustration, however, and one skilled in the art will readily ascertain that other optional applicators and applicator embodiments according to the invention can also be employed and that the invention can be equally and advantageously used in other fluid applicator apparatuses.

Referring initially to FIGS. 1 and 2, a fluid application or distribution assembly including the present invention is shown generally at 10 and is preferably incorporated into a free-standing apparatus for treating a textile fabric, web or other sheet-like substrate S traveling in a longitudinal direction D, in an ambient pressure P. In this regard, as mentioned above, the present invention can be used to treat a wide variety of substrates, including relatively thin, porous, permeable or semi-permeable substrate, including non-woven fibrous textiles, such as tissues or tissue-like fabrics, for example, or even woven porous or permeable substrates. Other substrate examples include, but are not limited to, webs or sheets of textile or non-textile materials, woven or non-woven or multi-stranded materials, flexible or non-flexible sheets or sheet-like materials, knitted substrates, cross-linked cellulose, loose fiber or impregnated substrates, thin, fragile tissue-like substrates, carpets or other floor coverings, continuous filament substrates, and other substrates known to those skilled in the art that are at least partially permeable.

The exemplary apparatus 10 shown in the drawings has a suitable floor-supported frame 12, including opposed end frame members 14 in a generally parallel and upright arrangement laterally spaced sufficiently to permit the substrate S to travel longitudinally in direction D therebetween. The distribution assembly 10 includes an applicator 16 extending transversely or laterally across the path of the longitudinally traveling substrate S. Although the example shown in FIG. 1 includes the assembly 10 arranged for treating the substrate S from above, the applicator 16 can alternatively be arranged and positioned for applying the fluid from either side of a vertically disposed longitudinally traveling substrate or even from below a horizontally disposed longitudinally traveling substrate.

The exemplary applicator 16 includes a fluid inlet 18 for receiving the preferably foamed treating fluid 24 from a foam generator or other source of treating fluid. An applicator nozzle 20 is also provided on the applicator 16, with a transversely or laterally elongated discharge opening 22 for depositing the treating fluid 24 onto the surface of its first or upper side, with very minimal or no penetration into the substrate S. Preferably, the applicator nozzle discharge opening 22 has a lateral dimension that is generally coextensive with the lateral width of the longitudinally traveling substrate S.

The applicator assembly 16 can also include a low-pressure chamber 40 on the second or opposite side of the substrate S. The low-pressure chamber 40 includes side walls 42, a bottom 44, an inlet opening 46 disposed closely adjacent the second side of the substrate S, and an outlet 48. Like the discharge opening 22 of the nozzle 20, the lateral dimension of the inlet opening 46 of the low-pressure chamber 40 is preferably generally coextensive with the lateral width of the longitudinally traveling substrate S and is generally longitudinally aligned to overlap the nozzle 20 from an upstream side thereof relative to the direction of travel of the substrate S.

The outlet 48 of the low-pressure chamber 40 is connected in fluid communication with an inlet 54 of a fan or other air conveying mechanism 52, which also includes an outlet 56. One skilled in the art will readily recognize that the air conveying mechanism 52 can optionally be a fan, as shown for example in the drawings, a blower, a vacuum pump, or any of a wide variety of known devices capable of producing a relatively low chamber pressure P1. However, it should be noted that the chamber pressure P1 must be somewhat lower than the ambient pressure P, but not so much lower that thin or fragile substrates S will be downwardly deformed toward, or drawn into, the low-pressure chamber 40 or broken.

Because the chamber pressure P1 is somewhat lower than the ambient pressure P, at least a substantial portion of the air boundary layer or other air layer 58 from the first side of the traveling permeable substrate S is drawn through the traveling permeable substrate S and into the low-pressure chamber 40, where it can then be exhausted by way of the outlet 56 of the fan 52. This substantially minimize the thickness of the air boundary layer 58, which results primarily from high-speed longitudinal movement of the substrate S. The reduction of virtually all or at least a substantial portion of this air barrier or boundary layer 58 clears the way for the preferably foamed treating fluid 24 to be lightly deposited onto the first side surface of the substrate S from the nozzle 20. As mentioned above, this chamber pressure P1 must be somewhat lower than the ambient pressure P, but not so much lower than the ambient pressure P that thin or fragile substrates S will be downwardly deformed toward, or drawn into, the low-pressure chamber 40, but should also not be so much lower that the treating fluid 24 is caused to penetrate into the permeable substrate S.

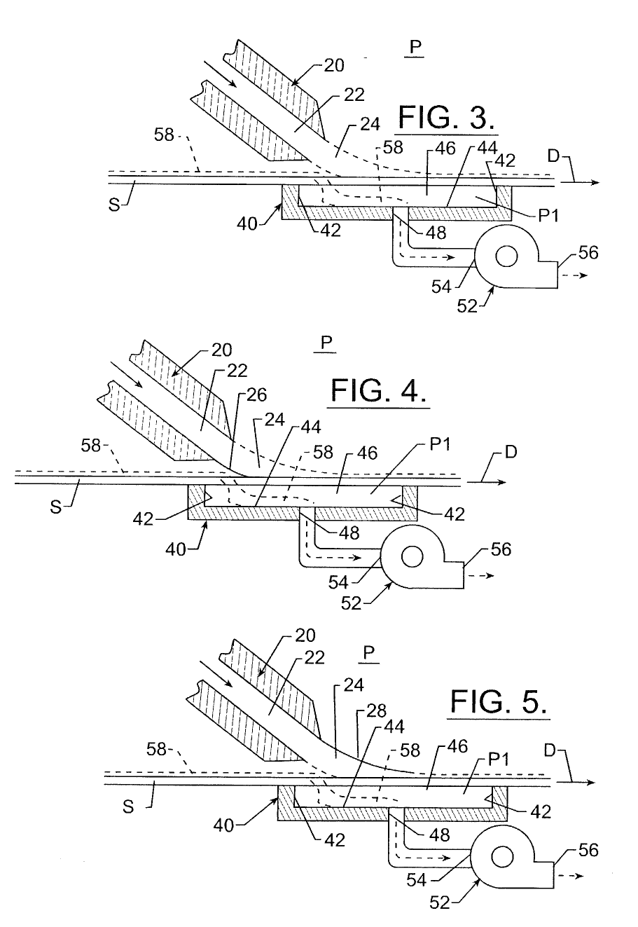

In order to further facilitate this goal, the applicator assembly 16 can also include an upper thin flexible lip 28, a lower thin flexible lip 26, or both, extending from respective upper and lower sides of the laterally elongated nozzle discharge opening 22, as illustrated in FIGS. 3 through 7 and discussed in more detail below. The upper flexible lip 24 is actually held out of contact with the first side by the presence of the treating fluid 24 and prevents the preferably foamed treating fluid 24 from disintegrating or otherwise breaking down as it traverses the gap between the nozzle discharge opening 22 and the first side of the substrate S. In this way, the thin flexible lip exerts almost no perceptible force on the substrate S itself, but greatly facilitates the application and “spreading” of a very light surface coating of treating fluid.

Similarly, the lower thin flexible lip 26 very lightly contacts the first side surface of the substrate S just enough to displace a substantial portion of the above-mentioned boundary layer or other air 58, prior to, or upstream of, the application of the treating fluid 24. It is often desirable to have both an upper flexible lip 28 and a lower flexible lip 26, depending upon the material, thickness, texture, fragility and/or speed of the substrate S. Also, depending upon these factors, the use of either or both of the upper and lower flexible lips 28 and 26 can be included with or without the above-described low-pressure chamber 40, especially in applications where the speed or texture of the substrate S causes a portion of the boundary layer air 58 to slip under the lower flexible lip 26. As mentioned above, the lateral dimension of the upper and lower lips 28 and 26 are preferably generally coextensive with the lateral width of the substrate S.

In the specific example shown in FIG. 3, an application of the present invention is illustrated where the material, thickness, texture, fragility and/or speed of the traveling permeable substrate S do not require any flexible lips between the nozzle 20 and the substrate S. Instead, in this exemplary application, only the above-described low-pressure chamber 40 is needed to exhaust the boundary layer air 58 from the surface of the first side of the substrate S, just upstream of the application of the preferably foamed treating fluid 24. As mentioned above the substantial elimination of this inhibiting barrier of air facilitates the light coating of the treating fluid 24 onto the surface of the substrate S, with substantially no penetration.

In FIG. 4, due to the various factors mentioned above, this exemplary application of the present invention requires the addition of the lower flexible lip 26 to aid in the substantial elimination of the barrier created by the boundary or other air layer 58, acting in conjunction with the low-pressure chamber 40 and its related components described above.

FIG. 5 illustrates another exemplary application of the present invention, where the material, thickness, texture, fragility and/or speed of the traveling permeable substrate S are such that it is either unnecessary or undesirable to have a lower flexible lip in contact with the substrate S. However, due to these factors, it is advantageous to include both the upper flexible lip 28 and the low-pressure chamber 40 and its related components. In this example, the upper flexible lip 28 substantially prevents breakdown of the preferably foamed treating fluid 24 and is actually held out of contact with the substrate by the treating fluid 24.

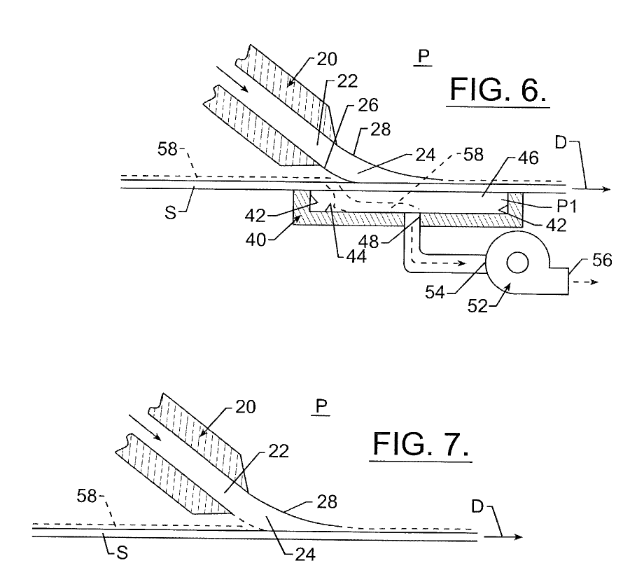

In FIG. 6, the above-mentioned substrate factors require the provision of both the lower and upper flexible lips 26 and 28, as well as the low-pressure chamber 40 and related components. In marked contrast to the application in FIG. 6, however, the substrate factors present in the example of FIG. 7 require only the upper flexible lip 28 to substantially prevent breakdown of the preferably foamed treating fluid 24 and properly coating the substrate substantially without penetration.

Although the upper limit on substrate speed, given the other factors mentioned above, that is attainable with the present invention is not yet known, speeds of 100 meters/minute have been attained with substrates composed of nonwoven glass fibers or other nonwoven materials. Preliminary investigations have indicated that the gap between the nozzle discharge opening 22 and the substrate S is most typically approximately ⅛ inch, but can range from 1/16 inch or smaller, up to approximately ¾ inch, or perhaps even more. Preferably the angular orientation of the nozzle 20 relative to the substrate S is a generally acute angle, but it can range from approximately ten degrees to as great as approximately ninety degrees.

The flexible lips 26 and 28 are preferably composed of thin flexible materials, such as plastics, thin flexible metals, for example, or from other suitable flexible materials or composites that will occur to those skilled in the art. A typical “longitudinal” width of these flexible lips is approximately ¾ inch, but can range from approximately ½ inch or less, to approximately two inches, or even more, depending upon the above-mentioned substrate factors and the materials from which the lips are composed, for example. Again, depending upon these same factors, a typical lip thickness can be approximately 0.003 inch, but can range from approximately 0.001 inch, or even smaller, to approximately 0.015 inch, or even larger. Finally, it should be noted that where both of the lower and upper flexible lips 26 and 28 are used, the lips can have the same or different lateral widths, depending upon the substrate and lip factors mentioned above.

The foregoing discussion discloses and describes merely exemplary embodiments of the present invention for purposes of illustration. One skilled in the art will readily recognize from such discussion, and from the accompanying drawings and claims, that various changes, modifications, and variations can be made therein without departing from the substance, spirit or scope of the present invention, as defined in the following claims.

What is claimed is:

1. In an applicator for applying a fluid material to a longitudinally traveling permeable substrate, the improvement comprising:
a fluid dispensing nozzle positionable adjacent a first side of the traveling permeable substrate for depositing the fluid material onto the first side of the traveling permeable substrate at ambient pressure; and
a low-pressure chamber positionable adjacent a second side of the traveling permeable substrate, said low-pressure chamber having a pressure therein that is lower than said ambient pressure in order to cause air from said first side of the traveling permeable substrate to flow through the traveling permeable substrate and into said low-pressure chamber.

2. The improvement according to claim 1, wherein the fluid material is a foamed material.

3. The improvement according to claim 1, further comprising an air conveying mechanism having an inlet and an outlet, said low-pressure chamber being in fluid communication with said inlet of said air conveying mechanism for exhausting the air from said low-pressure chamber.

4. The improvement according to claim 3, wherein said air conveying mechanism comprises a fan.

5. The improvement according to claim 3, wherein said low-pressure chamber is longitudinally positioned generally opposite said nozzle.

6. The improvement according to claim 1, further comprising a first flexible lip extending between said nozzle and the traveling permeable substrate.

7. The improvement according to claim 6, further comprising a second flexible lip extending between said nozzle and the traveling permeable substrate, said first and second flexible lips being spaced apart on opposite sides of the fluid material being deposited from said nozzle onto the first side of the traveling permeable substrate.

8. The improvement according to claim 7, said second flexible lip contacting the traveling permeable substrate prior to the fluid material being deposited thereon, and said first flexible lip being held out of contact with the traveling permeable substrate by the fluid material being deposited onto the traveling permeable substrate from said nozzle.

9. The improvement according to claim 6, wherein said nozzle has a laterally elongated discharge opening through which the fluid material is deposited onto the first side of the traveling permeable substrate, said first flexible lip being laterally elongated and having a lateral dimension at least substantially equal to the lateral dimension of the traveling permeable substrate.

10. The improvement according to claim 9, further comprising a second flexible lip extending between said nozzle and the traveling permeable substrate, said first and second flexible lips being spaced apart on opposite sides of the fluid material being deposited from said nozzle onto the first side of the traveling permeable substrate, said second flexible lip being laterally elongated and having a lateral dimension at least substantially equal to the lateral dimension of the traveling permeable substrate.

11. The improvement according to claim 10, said second flexible lip contacts the traveling permeable substrate prior to the fluid material being deposited thereon, and said first flexible lip being held out of contact with the traveling permeable substrate by the fluid material being deposited onto the traveling permeable substrate from said nozzle.

12. The improvement according to claim 9, wherein said nozzle is disposed at an acute angle with respect to the traveling permeable substrate.

13. The improvement according to claim 12, further comprising a second flexible lip extending between said nozzle and the traveling permeable substrate, said first and second flexible lips being spaced apart on opposite sides of the fluid material being deposited from said nozzle onto the first side of the traveling permeable substrate, said second flexible lip contacting the traveling permeable substrate prior to the fluid material being deposited thereon, and said first flexible lip being held out of contact with the traveling permeable substrate by the fluid material being deposited onto the traveling permeable substrate from said nozzle.

14. The improvement according to claim 13, wherein the fluid material is a foamed material.

15. In an applicator for applying a fluid material to a permeable longitudinally traveling substrate, the improvement comprising:
a fluid dispensing nozzle positionable adjacent a first side of the traveling permeable substrate for depositing the fluid material onto the first side of the traveling permeable substrate at ambient pressure; and
a flexible lip extending between said nozzle and the traveling permeable substrate.

16. The improvement according to claim 15, wherein the fluid material is a foamed material.

17. The improvement according to claim 15, further comprising a second flexible lip extending between said nozzle and the traveling permeable substrate, said first and second flexible lips being spaced apart on opposite sides of the fluid material being deposited from said nozzle onto the first side of the traveling permeable substrate.

18. The improvement according to claim 17, said second flexible lip contacting the traveling permeable substrate prior to the fluid material being deposited thereon, and said first flexible lip being held out of contact with the traveling permeable substrate by the fluid material being deposited onto the traveling permeable substrate from said nozzle.

19. The improvement according to claim 15, wherein said nozzle has a laterally elongated discharge opening through which the fluid material is deposited onto the first side of the traveling permeable substrate, said first flexible lip being laterally elongated and having a lateral dimension at least substantially equal to the lateral dimension of the traveling permeable substrate.

20. The improvement according to claim 19, further comprising a second flexible lip extending between said nozzle and the traveling permeable substrate, said first and second flexible lips being spaced apart on opposite sides of the fluid material being deposited from said nozzle onto the first side of the traveling permeable substrate, said second flexible lip being laterally elongated and having a lateral dimension at least substantially equal to the lateral dimension of the traveling permeable substrate.

21. The improvement according to claim 20, said second flexible lip contacts the traveling permeable substrate prior to the fluid material being deposited thereon, and said first flexible lip being held out of contact with the traveling permeable substrate by the fluid material being deposited onto the traveling permeable substrate from said nozzle.

22. The improvement according to claim 19, wherein said nozzle is disposed at an acute angle with respect to the traveling permeable substrate.

23. The improvement according to claim 22, further comprising a second flexible lip extending between said nozzle and the traveling permeable substrate, said first and second flexible lips being spaced apart on opposite sides of the fluid material being deposited from said nozzle onto the first side of the traveling permeable substrate, said, second flexible lip contacting the traveling permeable substrate prior to the fluid material being deposited thereon, and said first flexible lip being held out of contact with the traveling permeable substrate by the fluid material being deposited onto the traveling permeable substrate from said nozzle.

24. The improvement according to claim 23, wherein the fluid material is a foamed material.
